(19) United States
(12) Patent Application Publication
(10) Pub. No.: US 2011/0096616 A1
(43) Pub. Date: Apr. 28, 2011

(54) SENSE AMPLIFIER CIRCUIT TO ENABLE SPEEDING-UP OF READOUT OF INFORMATION FROM MEMORY CELLS

(75) Inventors: Shuichi KUBOUCHI, Tokyo (JP); Yoshiro RIHO, Tokyo (JP)

(73) Assignee: Elpida Memory, Inc.

(21) Appl. No.: 12/904,337

(22) Filed: Oct. 14, 2010

(30) Foreign Application Priority Data
Oct. 23, 2009 (JP) 2009-244359

(51) Int. Cl. G11C 7/06; H03L 5/00

(52) U.S. Cl. 365/207; 327/306

(57) ABSTRACT

A sense amplifier circuit, which is connected to a bit line and to an inverted bit line to which a voltage, inverted alternatively from a high level or a low level of a voltage applied to the bit line, is applied, includes a first resistance section reducing a voltage output from a memory cell through the inverted bit line, a second resistance section reducing a voltage output from a memory cell through the bit line, and an amplification section amplifying the first voltage reduced by the first resistance section and amplifying the second voltage reduced by the second resistance section.

This application is based upon and claims the benefit of priority from Japanese Patent Application No. 2009-244359 filed on Oct. 23, 2009, the content of which is incorporated by reference.

### BACKGROUND OF THE INVENTION

1. Field of the Invention

The present invention relates to a sense amplifier circuit and to a semiconductor device.

2. Description of the Related Art

In recent years, dynamic random access memories (DRAMs) have been widely used as memory for storing information used in an information processor. A folded bit line arrangement and an open bit line arrangement are known as methods of connecting memory cells in DRAMs.

Memory cells with an open bit line arrangement are said to be susceptible to noise in comparison with those with a folded bit line arrangement because the distance between the memory cell in which information is stored and a reference bit line used as a reference for a voltage output from the memory cell when the information is read out is large. Application of an open- bit arrangement to memory cells of a DRAM, however, enables setting the memory cell area of the DRAM to a value (6F² (F: the minimum process size)) smaller than that in the case of application of a folded bit line configuration to reduce the size of the DRAM.

JP2002-026294A, JP2003-324160A, JP2007-005502A and JP11-265995A disclose examples of open bit line arrangements.

FIG. 1 shows an example of a configuration of a memory cell array provided with such an open bit line arrangement. As shown in FIG. 1, in memory cell array ARY, each of a plurality of memory cells disposed so as to form a lattice is connected to one of bit lines BL1 to BLJ or to one of inverted bit lines /BL1 to /BLJ and to one of a plurality of word lines.

Inverted bit lines /BL is a bit line to which an inverted signal of a signal applied to bit line BL is applied. In the following description, a slash symbol “1” attached in front of a reference character denotes inversion of the potential on the signal line indicated by the reference character or inversion of the signal transmitted through the signal line.

In memory cell array ARY, a plurality of sense amplifier circuits SAC are provided in one-to-one correspondence with the bit lines. Each sense amplifier circuit SAC is connected to one of the bit lines and to one of the inverted bit lines.

In the example shown in FIG. 1, low-level information is stored in memory cell CL-1-1, while high-level information is stored in the memory cells other than memory cell CL-1-1.

As shown in FIG. 2, equalizer EQC, amplification section SA and Y switch SW are provided in each sense amplifier circuit SAC shown in FIG. 1.

When a high-level equalizer control signal is input from the outside to equalizer EQC through equalizer control line EQ, equalizer EQC performs an equalizing operation to equalize each of the potentials on bit line BL and inverted bit line /BL to the same voltage value as reference voltage V_{PRE} on precharge line VBLP.

Amplification section SA outputs a voltage representing high-level information onto one of two bit lines, which are bit line BL and inverted bit line /BL, and outputs a voltage representing low-level information onto the other of the two bit lines, on the basis of the potentials on bit line BL and inverted bit line /BL connected to the memory cell by using inverters IV1 and IV2.

When high-level Y control voltage is input to Y switch SW from YS driver (not shown) through Y switch line YS, Y switch SW turns on transistor Y1 or Y2 to output the voltage output from the amplification section SA and representing high-level information onto one of two signal lines, which are local input/output (I/O) line LIO and inverted local IO line /LIO, and the voltage representing low-level information onto the other of the two signal lines.

The layout of transistors Y1 and Y2 will be described briefly with reference to FIGS. 3 and 4.

Description will be made of a case where inverted local IO line /LIO and local IO line LIO are formed in one layer in a plurality of wiring layers; bit line BL and inverted bit line /BL are formed in one of the plurality of wiring layers; and the layer in which the local IO lines are formed and the layer in which the bit lines are formed are different from each other. If the layout is such that the local IO lines and the bit lines do not intersect each other, these signal lines may be formed in one layer.

As shown in FIG. 3, diffusion layer M1 of transistor Y1 shown in FIG. 2 is connected to inverted local IO line /LIO through contacts C300 and C400 and connected to inverted bit line /BL through contacts C100 and C200. Y switch line YS functions as a gate electrode of transistor Yl.

As shown in FIG. 4, diffusion layer M2 of transistor Y2 shown in FIG. 2 is connected to local IO line LIO through contacts C700 and C800 and connected to bit line BL through contacts C500 and C600. Y switch line YS functions as a gate electrode of transistor Y2.

When low-level information is read out from memory cell CL-1-1 in the example shown in FIG. 1, voltage that is inverted alternatively from the high and low levels of the voltage output from memory cell CL-1-1 to bit line BL1 is applied to bit lines BL2 to BLJ or inverted bit lines /BL2 to /BLJ to which the memory cells, other than memory cell CL-1-1 from which information is to be read out (hereinafter referred to as “background memory cells BG”), are connected.

Accordingly, when as shown in FIG. 5 amplification section SA amplifies the voltage output from memory cell CL-1-1 by turning on inverter IV2 shown in FIG. 2 at time t100 in cycle CYC200 and turning on inverter IV1 at time t200, the voltage on bit line BL1 connected to memory cell CL-1-1 and the voltage on bit lines BL2 to BLJ connected to background memory cells BG are in phase opposition to each other.

In this case, the voltage on bit lines BL2 to BLJ influences the voltages on the substrate, including diffusion layers M1 and M2, and the voltages on non-selected word lines WL2 to WLK. The voltages on non-selected word lines WL2 to WLK and the substrate act as array noise to have an influence on bit line BL1 as well, thereby influencing the voltage value of the voltage on bit line BL1 output from memory cell CL-1-1.

More specifically, the value of the voltage on bit line BL1 is increased, as indicated in the region surrounded by the broken line in FIG. 5, so that the time required for convergence to the voltage value representing low-level information read out from memory cell CL-1-1 is increased. As a result, the speed at which information is read out from the memory cell is reduced.

Also, when high-level information is read out from memory cell CL-1-1, the value of the voltage on inverted bit line /BL1 is increased, as indicated in the region surrounded by the broken line in FIG. 6, so that the time required for convergence to the voltage value that represents low-level information that is output from amplification section SA, that is connected to bit line BL1, to inverted bit line /BL1 is increased.

### SUMMARY

In one embodiment, there is provided a sense amplifier circuit connected to a bit line and to an inverted bit line to which a voltage, inverted alternatively from a high level or a low level of a voltage applied to the bit line, is applied, that includes a first resistance section reducing a voltage output from a memory cell through the inverted bit line, a second resistance section reducing a voltage output from a memory cell through the bit line, and an amplification section amplifying the first voltage reduced by the first resistance section and amplifying the second voltage reduced by the second resistance section.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing a configuration of a related memory cell array with an open bit line arrangement;

FIG. 2 is a diagram showing an example of a configuration of a related sense amplifier circuit;

FIG. 3 is a diagram showing a first example of a configuration on a diffusion layer on which a transistor in a Y switch shown in FIG. 2 is formed;

FIG. 4 is a diagram showing a second example of a configuration on a diffusion layer on which a transistor in the Y switch shown in FIG. 2 is formed;

FIG. 5 is a diagram showing a first example of voltage waveforms respectively applied to bit lines, inverted bit lines, non-selected word lines and a substrate in a case where information is read out from a memory cell;

FIG. 6 is a diagram showing a second example of voltage waveforms respectively applied to the bit lines, the inverted bit lines, the non-selected word lines and the substrate in the case where information is read out from the memory cell;

FIG. 7 is a diagram showing an example of a configuration of a sense amplifier circuit in a first embodiment of the present invention;

FIG. 8 is a diagram showing a state of application of voltages to a memory cell from which information is to be read out and background memory cells other than the memory cell from which information is to be read out;

FIG. 9 is a diagram showing voltage waveforms respectively applied to bit lines, internal bit lines, inverted bit lines, internal inverted bit lines, non- selected word lines and a substrate in a case where information is read out from a memory cell;

FIG. 10 is a diagram showing an example of a configuration of a sense amplifier circuit in a second embodiment of the present invention; FIG. 11 is a diagram showing an example of a configuration on a diffusion layer on which a transistor in a Y switch shown in FIG. 10 is formed;

FIG. 12 is a diagram showing an example of a configuration on a diffusion layer on which a transistor in the Y switch shown in FIG. 10 is formed; and

FIG. 13 is a diagram showing a configuration of a sense amplifier circuit in a third embodiment of the present invention.

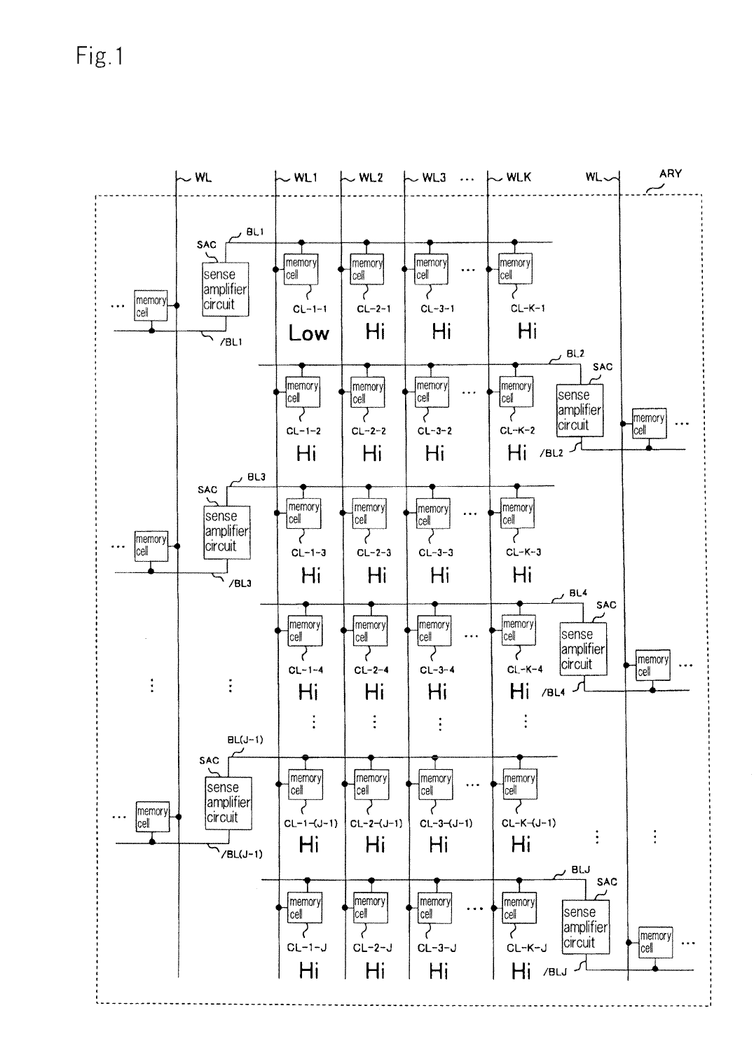

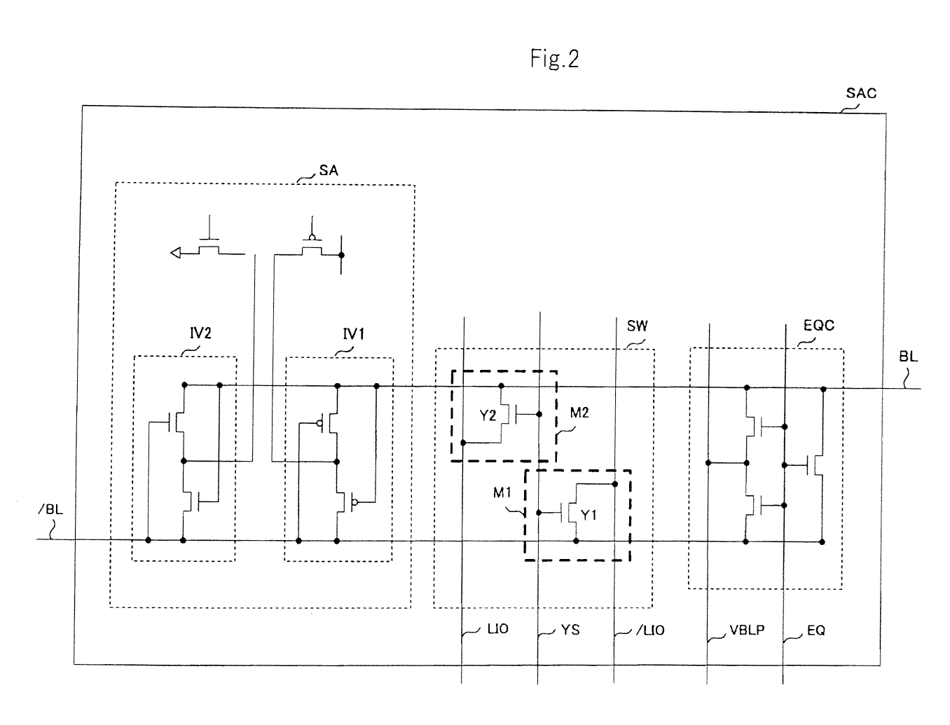

### DETAILED DESCRIPTION OF PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

Embodiments of a semiconductor device according to the present invention will be described below.

First Embodiment

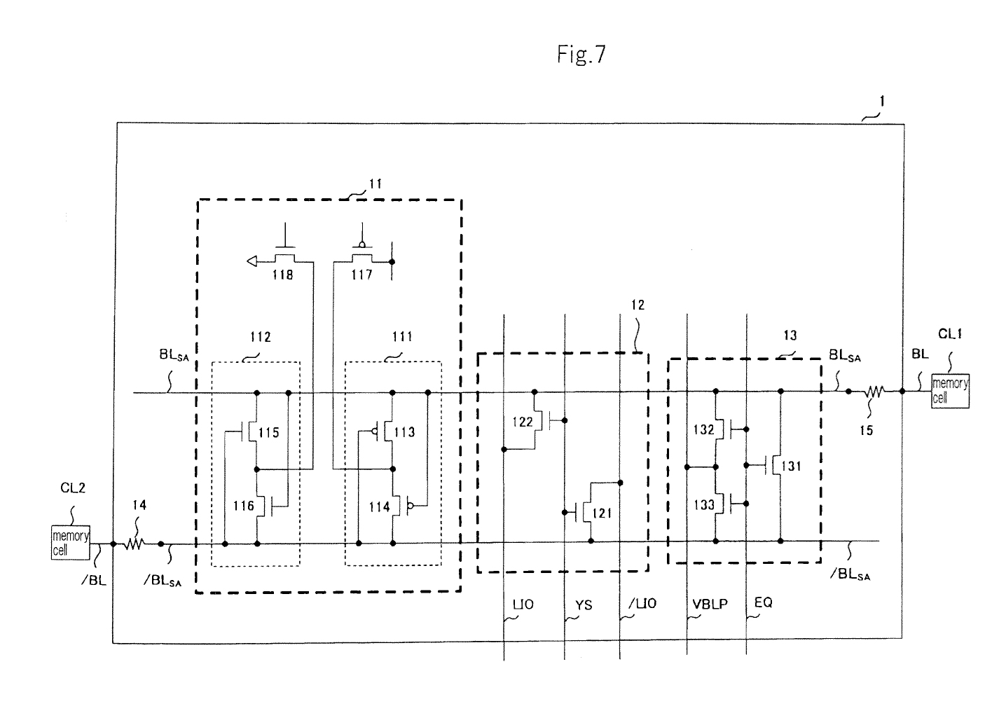

A semiconductor device according to a first embodiment of the present invention will be described. The configuration of sense amplifier circuit 1 provided in the semiconductor device in the present embodiment will first be described in detail with reference to FIG. 7.

As shown in FIG. 7, amplification section 11, Y switch 12 and equalizer 13 are provided in sense amplifier circuit 1. Internal bit line BL_{SA} provided in sense amplifier circuit 1 is connected to bit line BL through second resistance section 15. Also, internal inverted bit line /BL_{SA} provided in sense amplifier circuit 1 is connected to inverted bit line /BL through first resistance section 14.

In the first embodiment, first resistance section 14 and second resistance section 15 are resistance elements having a predetermined resistance component respectively.

Bit line BL is connected to memory cell CL1, while inverted bit line /BL is connected to memory cell CL2.

Sense amplifier circuit 1 reads out information from memory cells CL1 and CL2. The time at which information is read out from memory cell CL1 and the time at which information is read out from memory cell CL2 are different from each other.

When sense amplifier circuit 1 reads out information from memory cell CL1, the voltage representing the information stored in memory cell CL1 is applied to bit line BL. The voltage applied to bit line BL is input to amplification section 11 through internal bit line BL_{SA} after dropping across second resistance section 15.

When sense amplifier circuit 1 reads out information from memory cell CL2, the voltage representing the information stored in memory cell CL2 is applied to inverted bit line /BL. The voltage applied to inverted bit line /BL is input to amplification section 11 through internal inverted bit line /BL_{SA} after dropping across first resistance section 14.

Further, at the time that information from the memory cell is read out by sense amplifier circuit 1, the voltage inverted alternatively from the high and low levels of the voltage on internal inverted bit line /BL_{SA} is applied to internal bit line BL_{SA}.

The voltage which is dropped by first resistance section 14 corresponds to the first voltage. The voltage which is dropped by second resistance section 15 corresponds to the second voltage.

In equalizer 13, N-channel (Nch) transistors 131, 132, and 133 in which carriers are electrons are provided. Each of the gate electrodes of transistors 131, 132, and 133 is connected to equalizer control line EQ.

When a high-level equalizer control signal is input from the outside to equalizer 13 through equalizer control line EQ, equalizer 13 performs an equalizing operation to equalize the potential on internal inverted bit line /BL_{SA} and the potential on internal bit line BL_{SA} to each other by using transistor 131.

In this case, since both transistors 132 and 133 are turned on, reference voltage V_{PRE} on precharge line VBLP is applied to internal inverted bit line /BL_{SA} and internal bit line BL_{SA}. As a result, each of the potentials on internal inverted bit line /BL_{SA} and internal bit line BL_{SA} is equal to reference voltage V_{PRE}.

This reference voltage V_{PRE} is a reference voltage value for determination made by amplification section 11 as to whether the information stored in memory cell CL1 or CL2 is high-level information or low-level information. Reference voltage V_{PRE} is set in advance. Equalizer 13 performs equalization before amplification section 11 reads out the information from memory cell CL1 or CL2.

When a low-level equalizer control signal is input from the outside to equalizer 13 through equalizer control line EQ, equalizer 13 unmakes the connection between internal inverted bit line /BL_{SA} and internal bit line BL_{SA}, the connection between internal bit line BL_{SA} and precharge line VBLP and the connection between internal inverted bit line /BL_{SA} and precharge line VBLP.

Amplification section 11 is connected to internal bit line BL_{SA} and internal inverted bit line /BL_{SA}. Amplification section 11 is provided with inverter 111, inverter 112, and P-channel (Pch) transistors 117 and 118 in which carriers are positive holes.

Transistor 117 supplies a voltage for driving inverter 111. Transistor 118 supplies a voltage for driving inverter 112. The value of the voltage supplied to inverter 111 by transistor 117 is higher than the value of the voltage supplied to inverter 112 by transistor 118.

Amplification section 11 outputs the voltage representing high-level information to one of two bit lines, which are internal bit line BL_{SA} and internal inverted bit line /BL_{SA}, on the basis of the potential on internal bit line BL_{SA} and the potential on internal inverted bit line /BL_{SA}. Amplification section 11 also outputs the voltage representing low-level information to the other of the two bit lines. The potential on internal bit line BL_{SA} and the potential on internal inverted bit line /BL_{SA} change according to high-level or low-level information stored in memory cell CL1 or CL2.

The operation of amplification section 11 when the voltage representing low-level information is input through internal bit line BL_{SA} and when the voltage representing high-level information is input through internal inverted bit line /BL_{SA} will be described.

Transistor 114 is on and amplification section 11 amplifies the voltage output from transistor 117 and outputs the voltage onto internal inverted bit line /BL_{SA}. Transistor 113 is off and the voltage from transistor 117 is not output onto internal bit line BL_{SA}.

Also, transistor 115 is on and amplification section 11 amplifies the voltage output from transistor 118 and outputs the voltage onto internal bit line BL_{SA}. Transistor 116 is off and the voltage from transistor 118 is not output onto internal inverted bit line /BL_{SA}.

The operation of amplification section 11 when the voltage representing high-level information is input through internal bit line BL_{SA} and when the voltage representing low-level information is input through internal inverted bit line /BL_{SA} will be described.

Transistor 113 is on and amplification section 11 amplifies the voltage output from transistor 117 and outputs the voltage onto internal bit line BL_{SA}. Transistor 114 is off and the voltage from transistor 117 is not output onto internal inverted bit line /BL_{SA}.

Also, transistor 116 is on and amplification section 11 amplifies the voltage output from transistor 118 and outputs the voltage onto internal inverted bit line /BL_{SA}. Transistor 115 is off and the voltage from transistor 118 is not output onto internal bit line BL_{SA}.

When a low-level Y control voltage is input to Y switch 12 from YS driver (not shown) through Y switch line YS, Y switch 12 unmakes the connection between inverted local IO line /LIO and internal inverted bit line /BL_{SA} and the connection between local IO line LIO and internal bit line BL_{SA}.

Also, when the voltage value amplified by amplification section 11 becomes equal to the predetermined reference voltage value, a high-level Y control voltage is input to Y switch 12 from the YS driver (not shown) through the Y switch line YS. Y switch 12 then connects inverted local IO line /LIO and internal inverted bit line /BL_{SA} to each other and connects local IO line LIO and internal bit line BL_{SA} to each other.

Y switch 12 thereby outputs onto local IO line LIO the voltage that has been output onto internal bit line BL_{SA} by amplification section 11, and outputs onto inverted local IO line /LIO the voltage that has been output onto internal inverted bit line /BL_{SA} by amplification section 11.

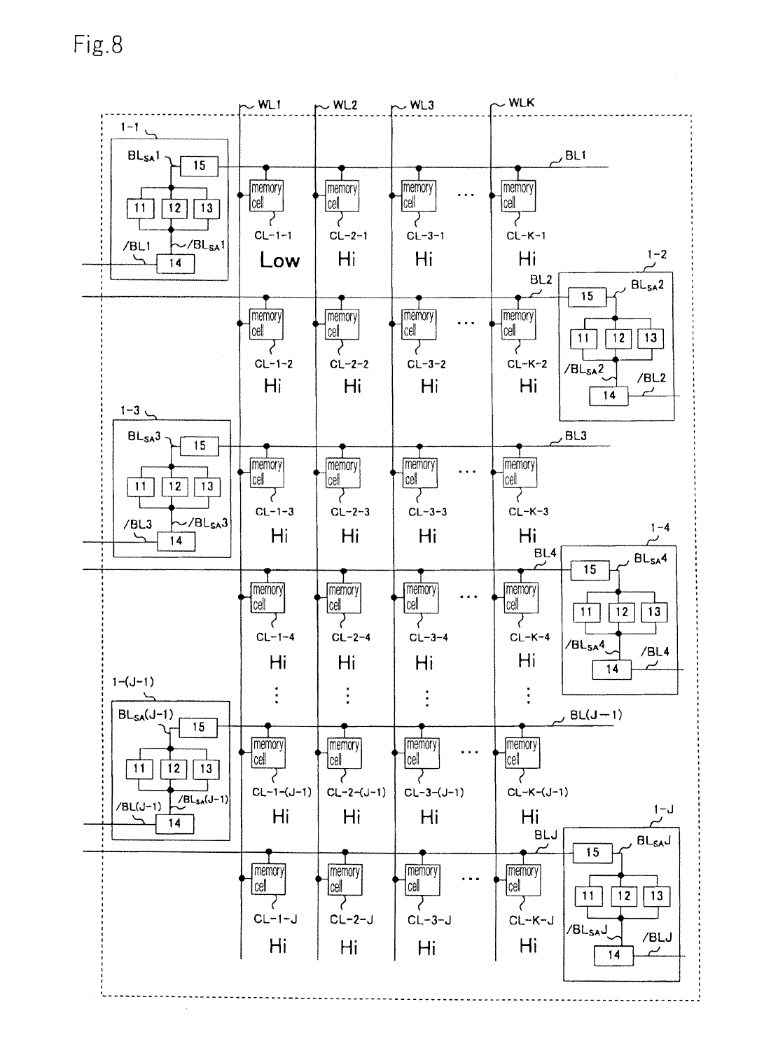

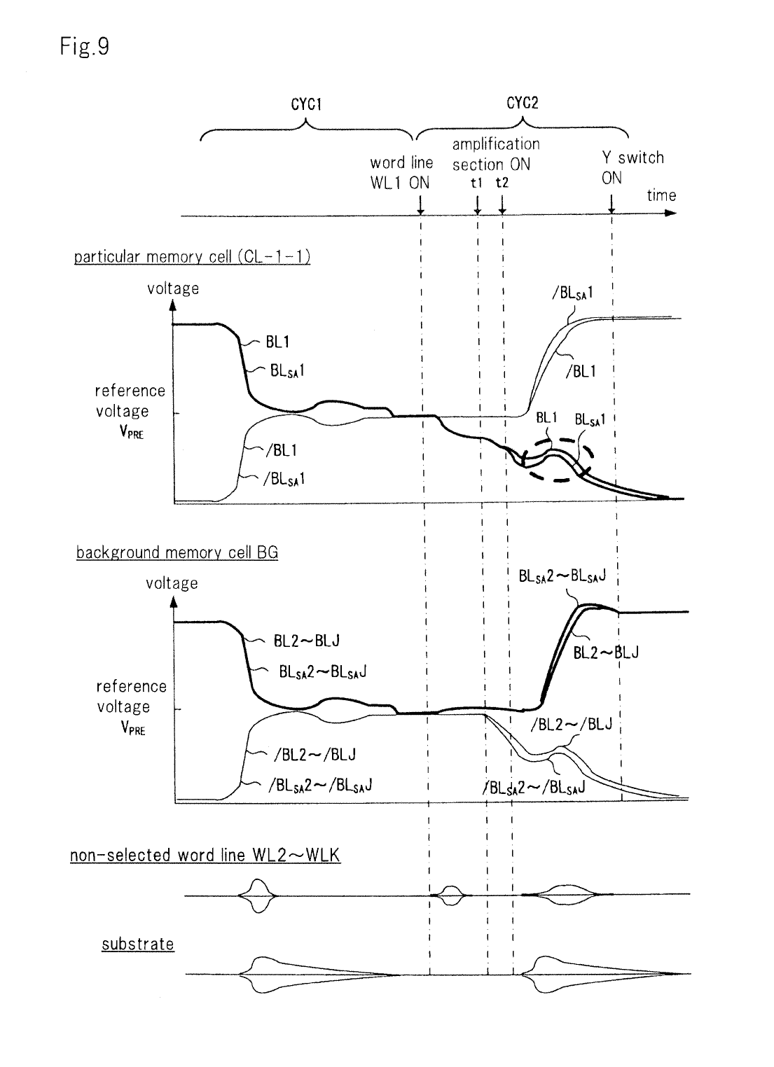

The operation when sense amplifier circuit 1 reads out information from the memory cells will be described with reference to FIGS. 8 and 9.

The following description is made by way of example with respect to a case where, as shown in FIG. 8, information indicating low level is stored in memory cell CL-1-1 in a plurality of memory cells CL-1-1 to CL-K-J disposed so as to form a lattice, while information indicating high level is stored in memory cells other than memory cell CL-1-1.

Also, since the operations to read out information respectively from memory cells CL-1-1 to CL-K-J are identical to each other, the following description is made by way of example with respect to the case of reading out information from memory cell CL-1-1 connected to word line WL1 and bit line BL1.

First, when the high-level equalizer control voltage is input to sense amplifier circuit 1-1 corresponding to bit line BL1 through equalizer control line EQ in cycle CYC1 shown in FIG. 9, sense amplifier circuit 1-1 sets the potential on internal bit line BL_{SA}1 and the potential on internal inverted bit line /BL_{SA}1 to the same voltage value as reference voltage V_{PRE}.

Thereafter, when word line WL1 and bit line BL1 are selected in cycle CYC2, the voltage representing low-level information stored in memory cell CL-1-1 is output to sense amplifier circuit 1-1 through bit line BL1.

Thereafter, at time t1, driver 118 provided in amplification section 11 in sense amplifier circuit 1-1 is turned on. Subsequently, at time t2, driver 117 is also turned on. Amplification section 11 then starts amplifying the voltage output from memory cell CL-1-1 through bit line BL1.

More specifically, amplification section 11 amplifies the high-level voltage from transistor 117 and outputs the voltage to internal inverted bit line /BL_{SA}1 according to voltage supplied through bit line BL1 and representing low-level information. Amplification section 11 also amplifies the low-level voltage from transistor 118 and outputs the voltage to internal bit line BL_{SA}1 according to the voltage supplied through inverted bit line /BL1 and representing high-level information.

In the example shown in FIG. 8, high-level information is stored in background memory cells BG other than memory cell CL-1-1. Accordingly, as shown in FIG. 9, voltage representing high-level information is applied to bit lines BL2 to BLJ connected to background memory cells BG. Also, the low-level voltage inverted from the level of the voltage applied to bit lines BL2 to BLJ is applied to inverted bit lines /BL2 to /BLJ.

Thereafter, when sense amplifier circuit 1-1 shown in FIG. 8 amplifies the voltage on bit line BL1 read out from memory cell CL-1-1, the voltage on bit lines BL2 to BLJ shown in FIG. 9 also has an influence on bit line BL1 through non-selected word lines WL2 to WLK and through the substrate (not shown). The value of the voltage on bit line BL1 is thereby increased as shown in the region surrounded by the broken line in FIG. 9.

However, the voltage on bit line BL1 drops across second resistance section 15 when input to sense amplification section 11 in sense amplifier circuit 1-1. The voltage reduced by the voltage drop as indicated in the region surrounded by the broken line in FIG. 9 is input to amplification section 11 through internal bit line BL_{SA}1.

Thereafter, when the value of the voltage amplified by amplification section 11 becomes equal to the predetermined reference voltage value, the high-level Y control voltage is input to Y switch 12 from the YS driver (not shown) and Y switch 12 outputs onto local IO line LIO the voltage that has been output onto internal bit line BL_{SA} by amplification section 11. Y switch 12 also outputs onto inverted local IO line /LIO the voltage that has been output onto internal inverted bit line /BL_{SA} by amplification section 11.

In the first embodiment of the present invention, as described above, even if the voltage on the bit lines or the inverted bit lines connected to the background memory cells influences the voltage on the bit line or the inverted bit line connected to the memory cell from which information is to be read out, the influenced voltage drops before being input to amplification section 11.

Thus, it is possible to limit the rise of the voltage input to amplification section 11 and to limit the increase in the time required for convergence to the voltage value representing low-level information read out from the memory cell from which the information is to be read out. Thus, it is possible to avoid a reduction in the speed at which information from the memory cell is read out.

First resistance section 14 shown in FIG. 7 may have any resistance value as long as the resistance value is within the range in, which the influence of the voltage on inverted bit lines /BL connected to background memory cells BG, on the voltage on inverted bit line /BL connected to the memory cell from which information is to be read out, can be reduced.

Also, second resistance section 15 shown in FIG. 7 may have any resistance value as long as the resistance value is within the range in, which the influence of the voltage on bit lines BL connected to background memory cells BG, on the voltage on bit line BL connected to the memory cell from which information is to be read out, can be reduced.

From the results of a simulation made by the inventor of the present invention, it has been confirmed that the above-described limitation effect can be obtained, for example, when each of the resistance values of first resistance section 14 and second resistance section 15 is ten to several ten kiloohms.

Second Embodiment

A semiconductor device in a second embodiment of the present invention will be described.

In the semiconductor device in the first embodiment, first resistance section 14, which is a resistance element, is provided between inverted bit line /BL and sense amplifier circuit 1, and second resistance section 15, which is another resistance element, is provided between bit line BL and sense amplifier circuit 1, as shown in FIG. 7.

In the case where resistance elements are added as components of first resistance section 14 and second resistance section 15, however, the memory cell area of the DRAM is increased.

In the second embodiment, a reduction in the speed at which information from memory cells is read out is avoided while avoiding an increase in memory cell area.

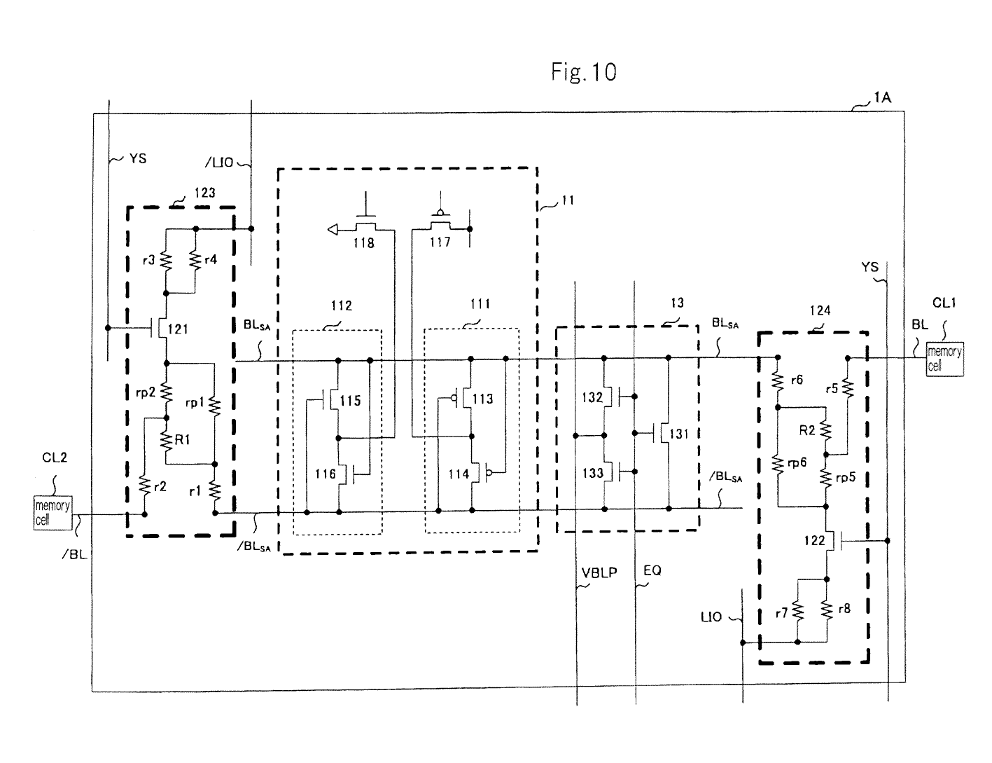

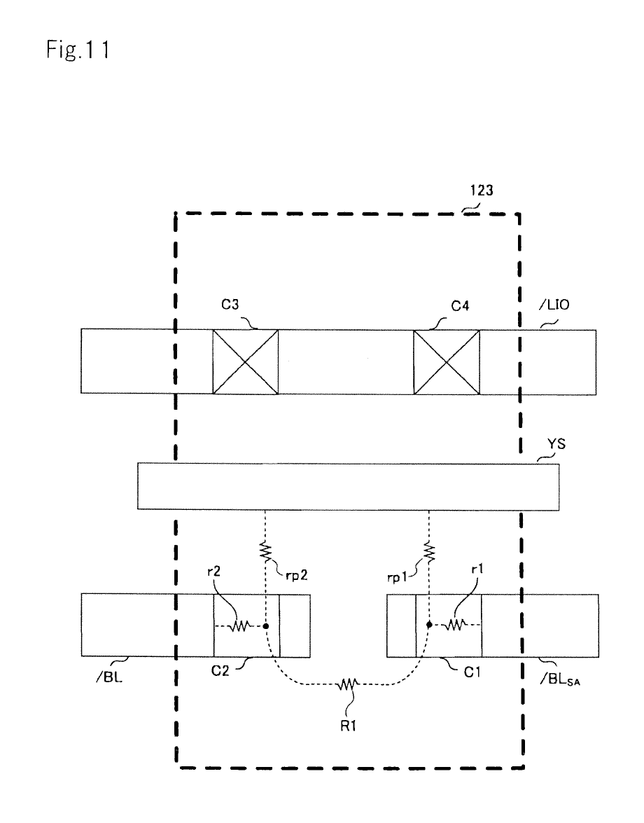

In the semiconductor device in the second embodiment, sense amplifier circuit 1A is provided in place of sense amplifier circuit 1 shown in FIG. 7. The configuration of sense amplifier circuit 1A will be described in detail with reference to FIG. 10.

Sense amplifier circuit 1A differs from sense amplifier circuit 1 in the first embodiment in that, as shown in FIG. 10, transistor 121 shown in FIG. 7 is disposed on the inverted bit line /BL side and transistor 122 shown in FIG. 7 is disposed on the bit line BL side.

Transistor 121 shown in FIG. 10 outputs onto inverted local IO line /LIO the voltage that has been output onto internal inverted bit line /BL_{SA} by amplification section 11. Also, transistor 122 outputs onto local IO line LIO the voltage that has been output onto internal bit line BL_{SA} by amplification section 11.

Transistor 121 is formed on diffusion layer 123 indicated by the broken line in FIG. 10, while transistor 122 is formed on diffusion layer 124 indicated by the broken line in FIG. 10.

Transistor 121 corresponds to the first switching transistor. Transistor 122 corresponds to the second switching transistor.

In the second embodiment, a “parasitic resistance component existing on diffusion layer 123” on which transistor 121 is formed is used as a resistance component of first resistance section 14, as described with reference to FIG. 11.

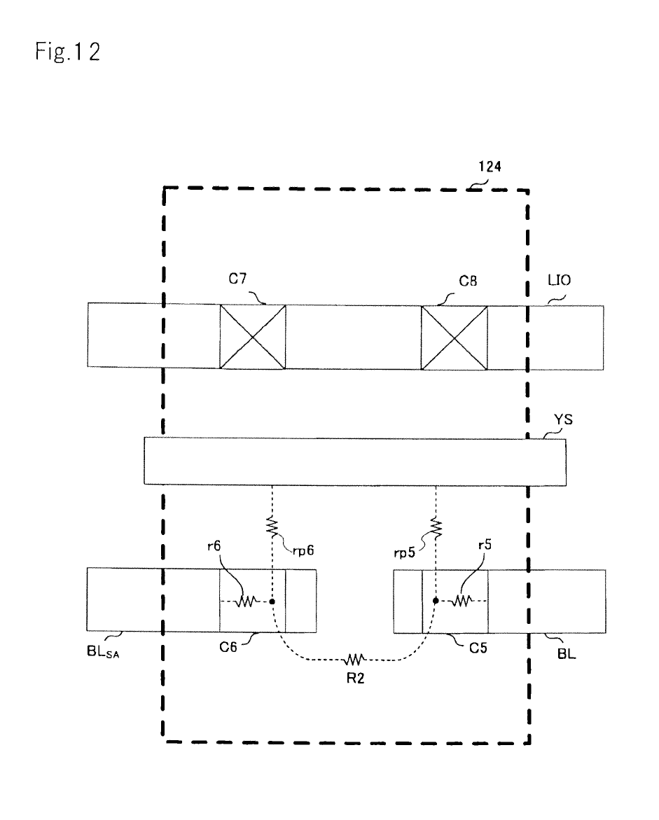

Also, in the second embodiment, a “parasitic resistance component existing on diffusion layer 124”, on which transistor 122 is formed, is used as a resistance component of second resistance section 15, as described with reference to FIG. 12.

That is, resistors R1, rp1, rp2, r1, r2, r3, and r4 on diffusion layer 123 shown in FIG. 10 are not actual resistance elements but represent a parasitic resistance component between contacts C1 and C2 shown in FIG. 11, a parasitic resistance component between contact C1 and Y switch line YS, a parasitic resistance component between contact C2 and Y switch line YS, and contact resistances of contacts C1 to C4, schematically illustrated in an electrical equivalent circuit.

Also, resistors R2, rp5, rp6, r6, r6, r7, and r8 on diffusion layer 124 shown in FIG. 10 are not actual resistance elements but represent a parasitic resistance component between contacts C5 and C6 shown in FIG. 12, a parasitic resistance component between contact C5 and Y switch line YS, a parasitic resistance component between contact C6 and Y switch line YS, and contact resistances of contacts C5 to C8, schematically illustrated in an electrical equivalent circuit.

Concrete examples of the disposition of diffusion layers 123 and 124 constituting sense amplifier circuit 1A in the second embodiment will be described with reference to FIGS. 11 and 12.

Description will first be made of diffusion layer 123 with reference to FIG. 11.

As shown in FIG. 11, Y switch line YS, inverted local IO line /LIO, inverted bit line /BL and internal inverted bit line /BL_{SA} are disposed in the lowermost wiring layer of a plurality of wiring layers formed on diffusion layer 123 shown in FIG. 10, with insulating film interposed therebetween.

Contacts C1, C2, C3, and C4 for making connections between these wiring lines and diffusion layer 123 of transistor 121 are provided on diffusion layer 123.

Contact C1 connects the drain electrode of transistor 121 and internal inverted bit line /BL_{SA} to each other. Contact C2 connects the drain electrode of transistor 121 and inverted bit line /BL to each other. Each of contacts C3 and 04 connects the source electrode of transistor 121 and inverted local IO line /LIO to each other.

Contacts C1, C2, C3, and C4 have contact resistances r1, r2, r3, and r4, respectively, as their contact resistance components.

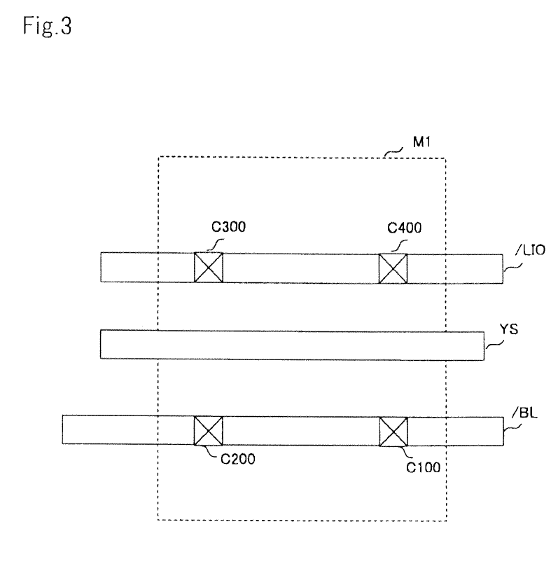

Contact C1 and contact C2 are not connected by a connection line and are not short-circuited. Therefore parasitic resistance R1 exists between contacts C1 and C2. The structure of diffusion layer 123 in the second embodiment is the same as the structure formed by disconnecting the connection line between contacts C100 and C200 in diffusion layer M1 shown in FIG. 3.

Further, in the example shown in FIG. 11, parasitic resistance rp1 exists between contact C1 and Y switch line YS, and parasitic resistance rp2 exists between contact C2 and Y-switch line YS.

Description will next be made of diffusion layer 124 with reference to FIG. 12.

As shown in FIG. 12, Y switch line YS, local IO line LIO, bit line BL and internal bit line BL_{SA} are disposed in the lowermost wiring layer of a plurality of wiring layers formed on diffusion layer 124 with insulating film interposed therebetween. Contacts C5, C6, C7, and C8 for making connections between these wiring lines and diffusion layer 124 of transistor 122 are provided on diffusion layer 124.

Contact C6 connects the drain electrode of transistor 122 and internal bit line BL_{SA} to each other. Contact C5 connects the drain electrode of transistor 122 and bit line BL to each other. Each of contacts C7 and C8 connects the source electrode of transistor 122 and local IO line LIO to each other.

Contacts C5, C6, C7, and C8 have contact resistances r5, r6, r7, and r8, respectively, as their contact resistance components.

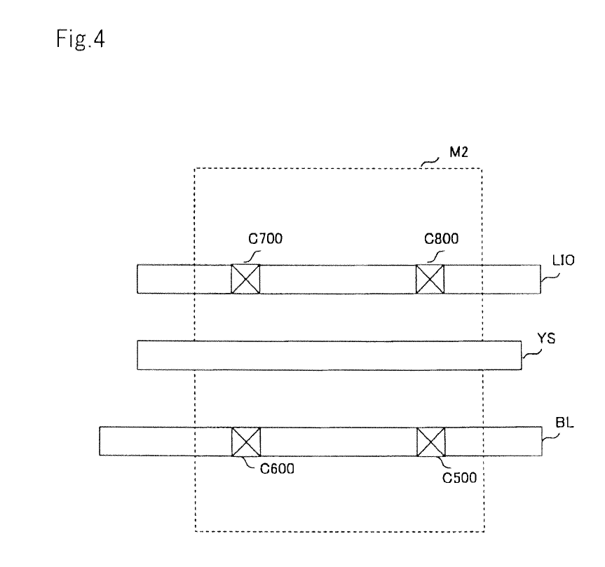

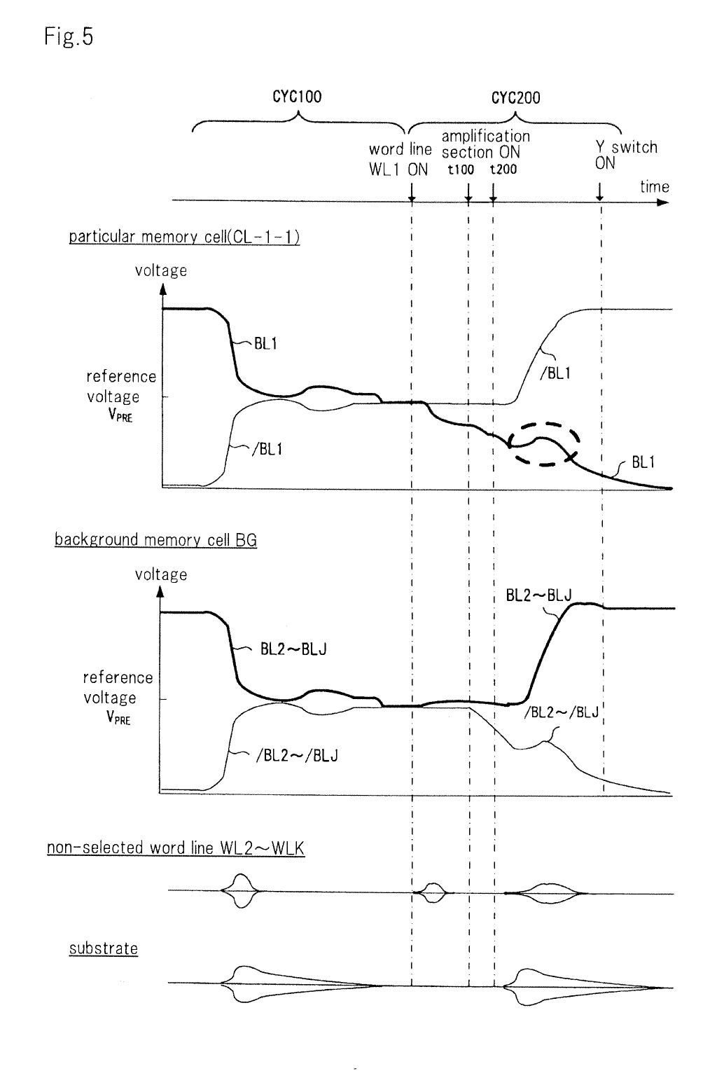

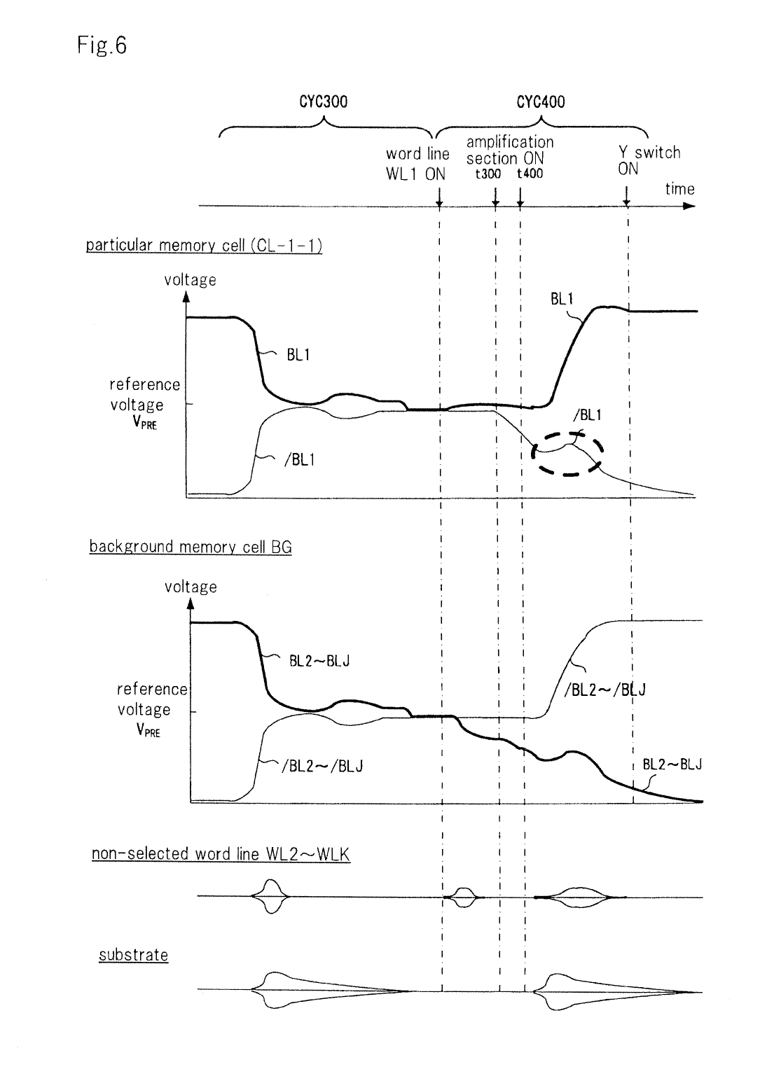

Contact C5 and contact C6 are not connected by a connection line and are not short-circuited. Therefore parasitic resistance R2 exists between contacts C5 and C6. The structure of diffusion layer 124 in the second embodiment is the same as the structure formed by disconnecting the connection line between contacts C500 and C600 in diffusion layer M2 shown in FIG. 4.

Further, in the example shown in FIG. 12, parasitic resistance rp5 exists between contact C5 and Y switch line YS, and parasitic resistance rp6 exists between contact C6 and Y-switch line YS.

The operation when sense amplifier circuit 1A in the second embodiment reads out information from the memory cells will be described by way of example illustrated in FIG. 8 with respect to a case where low-level information is read out from memory cell CL-1-1.

When memory cell CL-1-1 connected to word line WL1 and bit line BL1 is selected, the voltage representing low-level information stored in memory cell CL-1-1 is applied to sense amplifier circuit 1A through bit line BL1. Also, the voltage inverted from the level of the voltage on bit line BL1 and representing high-level information is applied to sense amplifier circuit 1A through inverted bit line /BL1.

Transistor 114 shown in FIG. 10 is then turned on and amplification section 11 amplifies the high-level voltage output from transistor 117 and outputs the voltage to internal inverted bit line /BL_{SA}1. Also, transistor 115 shown in FIG. 10 is then turned on and amplification section 11 amplifies the low-level voltage output from transistor 118 and outputs the voltage to internal bit line BL_{SA}1.

On the other hand, the voltage representing the high-level information stored in background memory cells BG other than memory cell CL-1-1 is applied to bit lines BL2 to BLJ connected to background memory cells BG. Also, the low-level voltage inverted from the high-level voltage on bit lines BL2 to BLJ is applied to inverted bit lines /BL2 to /BLJ.

Thereafter, when sense amplifier circuit 1A amplifies the voltage on bit line BL1 read out from memory cell CL-1-1, the voltage on bit lines BL2 to BLJ has an influence on bit line BL1 through non-selected word lines WL2 to WLK and the substrate.

However, the voltage on bit line BL1 drops by the parasitic resistance component existing between contacts C5 and C6 in diffusion layer 124 on which transistor 122 is formed before the voltage is input to amplification section 11. The voltage on bit line BL1 reduced by the voltage drop is input to amplification section 11 through internal bit line BL_{SA}1.

In the second embodiment, therefore, even when the voltage on the bit line BL connected to the memory cell from which information is to be read out rises, it is possible to limit the rise of the voltage input to amplification section 11 and to limit the increase in the time required for convergence to the voltage value representing low-level information read out from the memory cell. That is, it is possible to avoid a reduction in the speed at which information from the memory cell is read out.

Third Embodiment

A semiconductor device in a third embodiment of the present invention will be described.

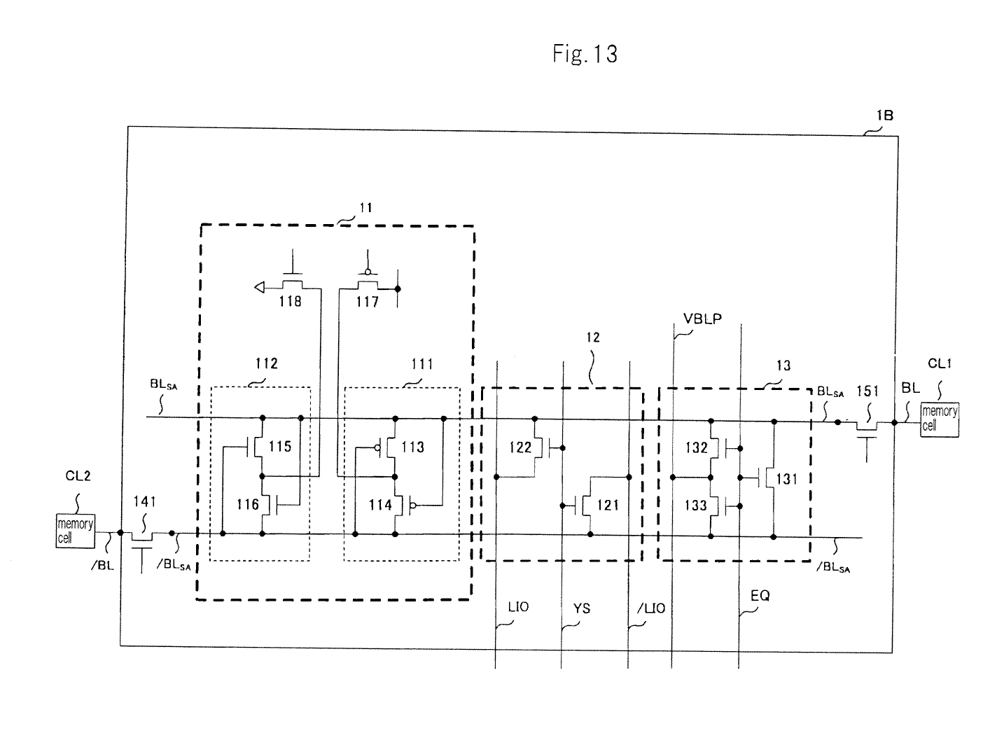

In the semiconductor device in the third embodiment, sense amplifier circuit 1B is provided in place of sense amplifier circuit 1 shown in FIG. 7. The configuration of this sense amplifier circuit 1B will be described in detail with reference to FIG. 13.

As shown in FIG. 13, sense amplifier circuit 1B differs from sense amplifier circuit 1 in the first embodiment in that first transistor 141 is provided in place of first resistance section 14 shown in FIG. 7 and second transistor 151 is provided in place of second resistance section 15 shown in FIG. 7.

In the third embodiment, an “on-resistance” which is the resistance value between the drain electrode and the source electrode of first transistor 141 is used as a resistance component of first resistance section 14 shown in FIG. 7. Also, the on-resistance of second resistance section 15 is used as a resistance component of second resistance section 15 shown in FIG. 7.

In the present embodiment, first transistor 141 and second transistor 151 are Nch transistors. However, first transistor 141 and second transistor 151 may alternatively be Pch transistors.

The drain electrode of first transistor 141 is connected to inverted bit line /BL, while the source electrode of first transistor 141 is connected to internal inverted bit line /BL_{SA}.

When the high-level control voltage is input from the outside to the gate electrode of first transistor 141, first transistor 141 connects inverted bit line /BL and internal inverted bit line /BL_{SA} to each other. The voltage output from the memory cell connected to inverted bit line /BL is then input to amplification section 11 through internal inverted bit line /BL_{SA}. The arrangement may alternatively be such that the high-level control voltage is input to the gate electrode of first transistor 141 at all times.

The drain electrode of second transistor 151 is connected to bit line BL, while the source electrode of second transistor 151 is connected to internal bit line BL_{SA}.

When the high-level control voltage is input from the outside to the gate electrode of second transistor 151, second transistor 151 connects bit line BL and internal bit line BL_{SA} to each other. The voltage output from the memory cell connected to bit line BL is then input to amplification section 11 through internal bit line BL_{SA}. The arrangement may alternatively be such that the high-level control voltage is input to the gate electrode of second transistor 151 at all times.

In the third embodiment, even when the voltage on inverted bit lines /BL connected to background memory cells BG influences the voltage on inverted bit line /BL connected to the memory cell from which information is to be read out, the influenced voltage is dropped due to the on-resistance of first transistor 141. The voltage reduced by the voltage drop is input to amplification section 11 through internal inverted bit line /BL_{SA}.

Also, even when the voltage on bit lines BL connected to background memory cells BG influences the voltage on inverted bit line BL connected to the memory cell from which information is to be read out, the influenced voltage is dropped due to the on-resistance of second transistor 151. The voltage reduced by the voltage drop is input to amplification section 11 through internal bit line BL_{SA}.

Thus, it is possible to avoid directly inputting into amplification section 11 the voltage that is influenced by the voltage on inverted bit line /BL or bit line BL connected to background memory cells BG and to limit the rise of the voltage input to amplification section 11.

It is possible to thereby limit the increase in the time required for convergence of the voltage on the bit line or the inverted bit line connected to the memory cell from which information is to be read out to the voltage value representing low-level information read out from the memory cell, and to avoid a reduction in the speed at which information is read out from the memory cell.

In the third embodiment, the high-level control voltage may not be input to first transistor 141 and to second transistor 151 at all times. For example, the arrangement may be such that the voltage inverted alternatively from the high and low levels of the voltage input to the gate electrode of first transistor 141 is applied to the gate electrode of second transistor 151.

In such a case, first transistor 141 connected to inverted bit line /BL is off at the time when information is read out from the memory cell connected to bit line BL while the high-level control voltage is being input to the gate electrode of second transistor 151 and while second transistor 151 is in the on-state.

It is, therefore, possible to unmake the connections between inverted bit lines /BL not connected to the memory cell from which information is to be read out and sense amplifier circuit 1B. Thus, it is possible to avoid exertion of the influence of the voltage on inverted bit lines /BL to which the memory cell from which information is to be read out is not connected on the voltage on bit line BL to which the memory cell from which information is to be read out is connected, and to thereby further improve the effect of reducing the reduction in the speed at which information is read out from the memory cell.

When information is read out from the memory cell connected to inverted bit line /BL, first transistor 141 and second transistor 151 perform the operations to be performed when information is read out from the memory cell connected to bit line BL, by changing the operations with each other. That is, first transistor 141 connects inverted bit line BL and sense amplifier circuit 1B to each other. On the other hand, second transistor 151 unmakes the connection between bit line BL and sense amplifier circuit 1B.

In this way, exertion of the influence of the voltage on bit lines BL not connected to the memory cell from which information is to be read out on the voltage on inverted bit line /BL connected to the memory cell from which information is to be read out can be avoided to further improve the effect of reducing the reduction in the speed at which information is read out.

Further, in such a case, inverted bit lines /BL or bit lines BL not connected to the memory cell from which information is to be read out are disconnected from sense amplifier circuit 1B, thereby reducing the parasitic capacitance of the bit lines or the inverted bit lines. As a result, the operation that is performed by amplification section 11 to amplify the voltage output from the memory cell can be performed in a shorter time period at the time when information is read out from the memory cell.

It is apparent that the present invention is not limited to the above embodiments, but may be modified and changed without departing from the scope and spirit of the invention.

What is claimed is:

1. A sense amplifier circuit connected to a bit line and to an inverted bit line to which a voltage, inverted alternatively from a high level or a low level of a voltage applied to the bit line, is applied, the sense amplifier circuit comprising:
a first resistance section reducing a voltage output from a memory cell through the inverted bit line;
a second resistance section reducing a voltage output from a memory cell through the bit line; and
an amplification section amplifying the first voltage reduced by the first resistance section and amplifying the second voltage reduced by the second resistance section.

2. The sense amplifier circuit according to claim 1, further comprising:
a first switching transistor outputting the first voltage amplified by the amplification section to the outside; and
a second switching transistor outputting the second voltage amplified by the amplification section to the outside,
wherein a resistance component of the first resistance section is formed only of a parasitic resistance component existing on a diffusion layer on which the first switching transistor is formed, and a resistance component of the second resistance section is formed only of a parasitic resistance component existing on a diffusion layer on which the second switching transistor is formed.

3. The sense amplifier circuit according to claim 1, wherein a first transistor is provided as the first resistance section, a second transistor is provided as the second resistance section, and
wherein a resistance component of the first resistance section is formed of an on-resistance element of the first transistor, and a resistance component of the second resistance section is formed of an on-resistance element of the second transistor.

4. A semiconductor device comprising
a plurality of memory cells and a plurality of sense amplifier circuits respectively connected to the plurality of memory cells through a plurality of bit lines or a plurality of inverted bit lines, each of the plurality of sense amplifier circuits including:
a first resistance section reducing a voltage output from the memory cell through the inverted bit line connected to the sense amplifier circuit;
a second resistance section reducing a voltage output from the memory cell through the bit line connected to the sense amplifier circuit; and
an amplification section amplifying the first voltage reduced by the first resistance section and amplifying the second voltage reduced by the second resistance section.

5. The semiconductor device according to claim 4, wherein the sense amplifier circuit further includes a first switching transistor outputting the first voltage amplified by the amplification section to the outside, and a second switching transistor outputting the second voltage amplified by the amplification section to the outside,
wherein a resistance component of the first resistance section is formed only of a parasitic resistance component existing on a diffusion layer on which the first switching transistor is formed, and a resistance component of the second resistance section is formed only of a parasitic resistance component existing on a diffusion layer on which the second switching transistor is formed.

6. The semiconductor device according to claim 4, wherein the sense amplifier has a first transistor as the first resistance section and a second transistor as the second resistance section, and
wherein a resistance component of the first resistance section is formed of an on-resistance element of the first transistor, and a resistance component of the second resistance section is formed of an on-resistance element of the second transistor.
